(19) United States
(12) Patent Application Publication
(10) Pub. No.: US 2026/0104635 A1
(43) Pub. Date: Apr. 16, 2026

(54) METHOD AND APPARATUS FOR OPTIMIZING OPTICAL PROXIMITY CORRECTION MODEL

(71) Applicant: Samsung Electronics Co., Ltd., Suwon-si (KR)

(72) Inventors: Kyoungyoon PARK, Suwon-si (KR); Useong KIM, Suwon-si (KR); Jinseok OH, Suwon-si (KR); Minho KIM, Suwon-si (KR); Dongyeul LEE, Suwon-si (KR)

(73) Assignee: Samsung Electronics Co., Ltd., Suwon-si (KR)

(21) Appl. No.: 19/325,847

(22) Filed: Sep. 11, 2025

(30) Foreign Application Priority Data
Oct. 11, 2024 (KR) 10-2024-0138821

(51) Int. Cl. G03F 1/36

(52) U.S. Cl. CPC G03F 1/36

(57) ABSTRACT

Provided is a method of optimizing an optical proximity correction (OPC) model, the method including: updating a kernel parameter of the OPC model including a linear combination of a kernel function; extracting a resist image by performing simulation on the OPC model, based on the updated kernel parameter; extracting first linear coefficients of the OPC model by executing Limited memory Broyden Fletcher Goldfarb Shanno with Bounds (L-BFGS-B) based on the resist image; and after the extracting of the first linear coefficients, extracting second linear coefficients of the OPC model by executing Inter Point Optimizer (IPO).

### CROSS-REFERENCE TO RELATED APPLICATION

This application is based on and claims priority under 35 U.S.C. § 119 to Korean Patent Application No. 10-2024-0138821, filed on Oct. 11, 2024, in the Korean Intellectual Property Office, the disclosure of which is incorporated by reference herein in its entirety.

### BACKGROUND

The inventive concepts relate to an optical proximity correction (OPC) method.

In a semiconductor process, a photolithography process, in which a mask is used, may be performed to form a pattern on a semiconductor substrate such as a wafer. The mask may be or include a pattern transcriptomic in which a pattern shape of an opaque material is formed on a transparent base-layer material. To briefly describe a process of fabricating a mask, first, after preparing a desired circuit and designing a layout of the circuit, design data obtained through optical proximity correction (OPC) is delivered as mask tape-out (MTO) design data. Next, mask data preparation (MDP) may be performed based on the MTO design data, and an exposure process and the like may be used on a substrate for a mask.

### SUMMARY

The inventive concepts provide a method and an apparatus for optimizing an optical proximity correction (OPC) model, by which the performance of the OPC model is improved.

In addition, the technical goals to be achieved by the inventive concepts are not limited thereto, and other technical goals may be clearly understood to those skilled in the art from the following descriptions.

According to an aspect of the inventive concepts, there is provided a method of optimizing an optical proximity correction (OPC) model, the method including updating a kernel parameter of the OPC model including a linear combination of a kernel function, extracting a resist image by performing simulation of the OPC model based on the updated kernel parameter, and extracting first linear coefficients of the OPC model by executing Limited memory Broyden Fletcher Goldfarb Shanno with Bounds (L-BFGS-B) based on the resist image.

According to another aspect of the inventive concepts, there is provided an electronic device including a memory configured to store at least one instruction, and a processor configured to, by executing the at least one instruction stored in the memory, update a kernel parameter of an optical proximity correction (OPC) model including a linear combination of a kernel function, extract a resist image by performing simulation of the OPC model based on the updated kernel parameter, and extract first linear coefficients of the OPC model by executing Limited memory Broyden Fletcher Goldfarb Shanno with Bounds (L-BFGS-B) based on the resist image.

According to another aspect of the inventive concepts, there is provided an optical proximity correction (OPC) method including receiving an input of a design layout of a target pattern, acquiring an aerial image from the design layout by performing simulation of a first OPC model to which optical phenomena in an exposure process are reflected, and optimizing a second OPC model, which acquires a resist image from the aerial image, by reflecting characteristics of a photoresist (PR) in the exposure process, wherein the optimizing of the second OPC model includes extracting a resist image by performing simulation on the second OPC model based on the updated kernel parameter, extracting first linear coefficients of the OPC model by executing Limited memory Broyden Fletcher Goldfarb Shanno with Bounds (L-BFGS-B), based on the resist image, and after the extracting of the first linear coefficients, extracting second linear coefficients of the OPC model by executing Inter Point Optimizer (IPO).

### BRIEF DESCRIPTION OF THE DRAWINGS

Embodiments will be more clearly understood from the following detailed description taken in conjunction with the accompanying drawings in which:

FIG. 1 is a flowchart schematically illustrating a process of an optical proximity correction (OPC) method according to at least one example embodiment;

FIG. 2 is a diagram schematically illustrating a process of an OPC method according to at least one example embodiment;

FIG. 3A is a flowchart schematically illustrating a process of a method of optimizing an OPC model, according to at least one example embodiment;

FIG. 3B is a diagram schematically illustrating a process of a method of optimizing an OPC model, according to at least one example embodiment;

FIG. 4 is a flowchart schematically illustrating a process of a method of optimizing an OPC model, according to at least one example embodiment;

FIG. 5 is a flowchart schematically illustrating first iteration of a method of optimizing an OPC model, according to at least one example embodiment;

FIG. 6 is a graph illustrating a result of comparing optimization rates of an OPC model in at least one example embodiment and a comparative example;

FIG. 7 is a flowchart schematically illustrating a method of optimizing an OPC model, according to at least one example embodiment;

FIG. 8 is a flowchart schematically illustrating first iteration and second iteration of a method of optimizing an OPC model according to at least one example embodiment;

FIG. 9 is a graph illustrating a result of comparing optimization rates of an OPC model in at least one example embodiment and a comparative example;

FIG. 10 is a flowchart schematically illustrating third iteration of a method of optimizing an OPC model according to at least one example embodiment;

FIG. 11 is a diagram schematically illustrating an electronic device according to at least one example embodiment;

FIG. 12 is a diagram illustrating an example of algorithms for implementing a method of optimizing an OPC model according to at least one example embodiment; and

FIG. 13 is a flowchart schematically illustrating a process of a method of fabricating a mask, the method including an OPC method according to at least one example embodiment.

### DETAILED DESCRIPTION OF THE EMBODIMENTS

Hereinafter, embodiments will be described with reference to the accompanying drawings. Same reference numerals will be used for same components on the drawings, and repeated descriptions thereof will not be given.

In the following embodiments, terms such as “first,” “second” are not used in a limitative sense, and are used to distinguish one component from others.

In the following embodiments, unless explicitly intended otherwise, singular expressions encompass plural expressions.

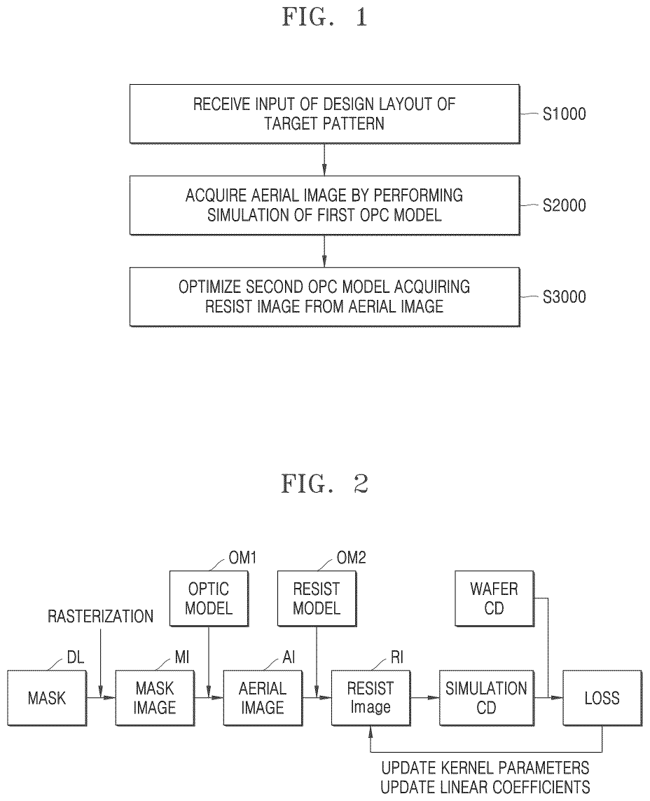

FIG. 1 is a flowchart schematically illustrating a process of a method of optimizing an OPC model according to at least one example embodiment, and FIG. 2 is a diagram schematically illustrating a process of an OPC method according to at least one example embodiment.

The OPC method is a method of inhibiting the occurrence of an optical proximity effect (OPE) (and/or the consequence thereof) by correcting a design layout on a pattern on a mask to overcome the OPE. The OPE is an effect occurring during an exposure process caused by influences between neighboring patterns due to minification of a pattern on a mask. In other words, the OPE causes changes in the size and the shape of the pattern formed on the wafer according to density/arrangement of the patterns on the mask, and the OPC method is performed to correct the change.

First, referring to FIG. 1, the OPC method according to at least one example embodiment may include receiving an input of a design layout for a target pattern (S1000), acquiring an aerial image by performing simulation of a first OPC model (S2000), and optimizing a second OPC model that acquires a resist image from the aerial image (S3000).

Referring to FIGS. 1 and 2, the input of the design layout for the target pattern may be received (S1000). Here, the target pattern may indicate a pattern to be formed on a substrate such as a silicon (Si) wafer. In other words, a pattern on a mask may be transferred to a substrate through an exposure process, and the target pattern may be formed on the substrate. Usually, a pattern on a mask may be projected to a smaller size and then transferred onto the wafer, as such the pattern on the mask may have a size greater than the size of the target pattern on the substrate. The design layout DL may indicate a layout of the pattern on the mask corresponding to the target pattern. Due to characteristics of an exposure process, a target pattern on the wafer and a pattern on a mask actually used in an exposure process may have different forms. However, the form of an initial design layout DL of the pattern on the mask may be substantially identical and/or similar to the form of the target pattern on the wafer. Next, a mask image MI, which is rasterized from the design layout DL, may be formed. By doing so, the mask image MI corresponding to the target pattern may be acquired.

The aerial image AI (or an optical image) may be acquired by performing simulation on the first OPC model OM1 (S2000). The first OPC model OM1 may include an optical OPC model. The first OPC model OM1 may be generated, in the exposure process, through optimization on one or more of a defocus stand (DS) position, a best focus (BF) position, and/or the like. In addition, the first OPC model OM1 may also be generated through, for example, generation of a mask image considering diffraction of light or an optical state of an exposure device itself. However, the first OPC model OM1 is not limited thereto and may be generated to include various contents related to optical phenomena in the exposure process.

The resist image RI may be acquired from the aerial image AI by performing simulation based on the second OPC model OM2. The second OPC model OM2 may include an OPC model to which characteristics of a photoresist (PR) are reflected. That is, the second OPC model OM2 may include an OPC model for the PR. Here, the characteristics of the PR may include characteristics due to one or more of components of the PR, a developer, a form, an inclination, a thickness of a PR pattern, and/or the like. The second OPC model OM2 may be generated by selecting and combining kernel functions from among various types of resist kernel functions. Here, a kernel function, which is a basis function used for nonparametric kernel estimation, may be used in the second OPC model OM2 to simulate characteristics of the resist image.

The OPC method according to at least one example embodiment may include improving or optimizing the second OPC model OM2 (S3000). The second OPC model OM2 may simulate physical and chemical responses of a complicated PR, and may have a model structure based on linear combination as shown in Equation 1, such that calculations may be rapidly performed. The optimizing of the second OPC model OM2 may include optimizing a kernel parameter θᵢ and a linear coefficient aᵢ.

$$R ( x ) = {\sum }_{i = 1}^{n} {a}_{i} {K}_{i} [ A ( x ) ; {θ}_{i} ] \qquad [ Equation 1 ]$$

Here, x may indicate a spatial position, R may indicate the resist image RI, aᵢ may indicate the linear coefficient, Kᵢ may indicate a kernel or an operator simulating physical and chemical responses of the PR, and θᵢ may indicate a kernel parameter needed for Kᵢ.

Referring to FIG. 2, the optimizing of the second OPC model OM2 may include determining a loss by comparing a critical dimension (CD) of the resist image RI with a CD of the pattern on the wafer. The CD of the resist image RI, which is acquired through simulation, may be understood as a simulation CD, and the CD of the pattern on the wafer may be understood as a wafer CD. The loss may be determined as a difference between the simulation CD and the wafer CD.

The optimizing of the second OPC model OM2 may include optimizing the kernel parameter θᵢ and the linear coefficient aᵢ of the OPC model such that the loss is reduced and/or minimized. As illustrated in FIG. 2, update on the kernel parameter and update on the linear coefficient may be performed according to the loss.

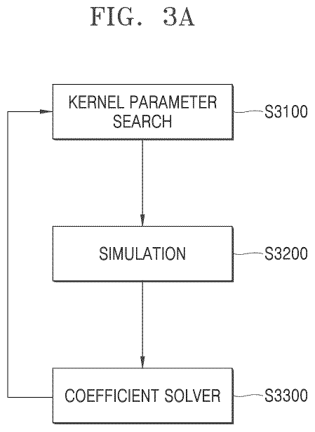

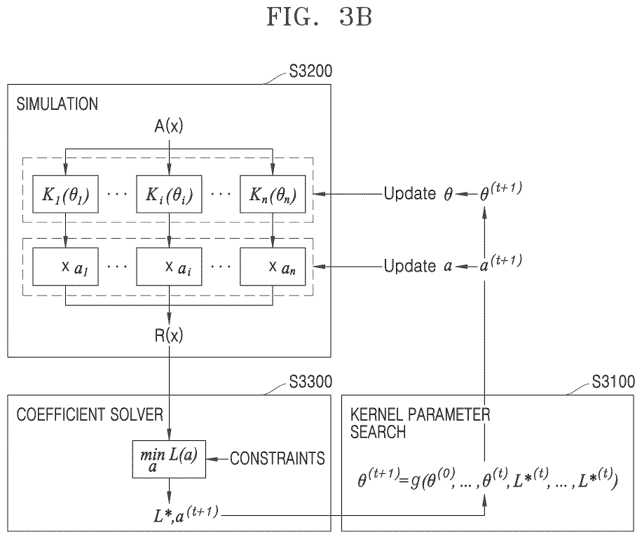

FIG. 3A is a flowchart schematically illustrating a process of the method of optimizing the OPC model, according to at least one example embodiment, and FIG. 3B is a diagram schematically illustrating a process of the method of optimizing the OPC model, according to at least one example embodiment. Hereinafter, the optimizing of the OPC model may indicate the optimizing of the second OPC model (see 3000 of FIGS. 1 and OM2 of FIG. 2).

Referring to FIGS. 3A and 3B, the method of optimizing the OPC model, according to various example embodiments, may include a kernel parameter search (S3100), a simulation (S3200), and a coefficient solver (S3300). In addition, the method of optimizing the OPC model may include one or more of an iteration, the interaction sequentially including the kernel parameter search, the simulation, and the coefficient solver.

The kernel parameter search (3100) may include identifying and updating a kernel parameter θᵢ. After updating the kernel parameter θᵢ in the kernel parameter search, the kernel (or the operator) Kᵢ and a resist image R(x) may be determined (e.g., calculated) in the simulation (S3200) based on the updated kernel parameter θᵢ. In the coefficient solver (S3300), the linear coefficient aᵢ may be optimized based on the kernel Kᵢ (or the operator) and the resist image R(x) determined in the simulation. Next, the process will return to the kernel parameter search, and the aforementioned iteration process may be repeated until a convergence condition is satisfied.

In the method of optimizing the OPC model, according to at least one example embodiment, various methods, such as genetic algorithm (e.g., Stochastic Gradient Ascent/Descent (SGA)), nonlinear optimization (e.g., constrained optimization by linear approximation (COBYLA)), gradient descent (e.g., Adaptive Moment Estimation (ADAM)), etc., may be used for optimizing the kernel parameter θᵢ.

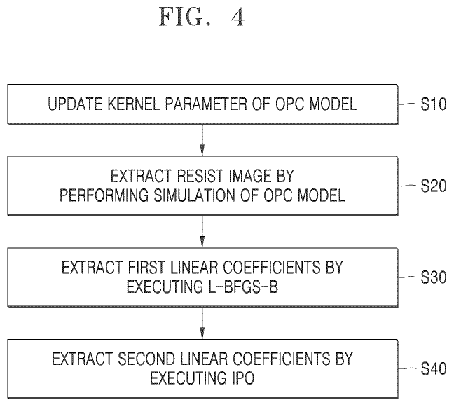

FIG. 4 is a flowchart schematically illustrating a process of the method of optimizing the OPC model, according to at least one example embodiment.

Referring to FIG. 4, the method of optimizing the OPC model, according to various example embodiments, may include updating a kernel parameter of the OPC model including linear combination of the kernel function (S10), extracting a resist image by performing simulation of the OPC model, based on the updated kernel parameter (S20), and extracting first linear coefficients by performing Limited memory Broyden Fletcher Goldfarb Shanno with Bounds (L-BFGS-B) based on the resist image (S30). In at least one example embodiment, the method of optimizing the OPC model may further include extracting second linear coefficients by executing Inter Point Optimizer (IPO) (S40).

Generally, a differentiation-based optimization method may be used. More particularly, Inter Point Optimizer (IPO), which may fulfill a linear inequality constraint in addition to a bound constraint, may be used. The IPO is a method of searching for an optimum while satisfying a hard constraint by using a log barrier, and convergence to the optimal solution ensures that the constraints are satisfied. In the IPO, the number (or amount) of calculations rapidly increases according to an increase in the number of parameters (here, the number of linear coefficients). Accordingly, time complexity of the algorithm tends to increase in an exponential function-scheme with respect to the number of parameters.

In the method of optimizing the OPC model, according to the various example embodiments, L-BFGS-B may be used to improve (or optimize) the linear coefficients. As a time complexity of the algorithm of L-BFGS-B is proportional to the number of parameters (here, the number of linear coefficients), the linear coefficient may be optimized at a high rate. In addition, by using L-BFGS-B, only a few recent vectors are stored without storing an entire Hessian matrix, use of the memory may be reduced as much as possible even large-scaled optimization problems, and as an upper limit and a lower limit may be set, the bound constraint may be fulfilled.

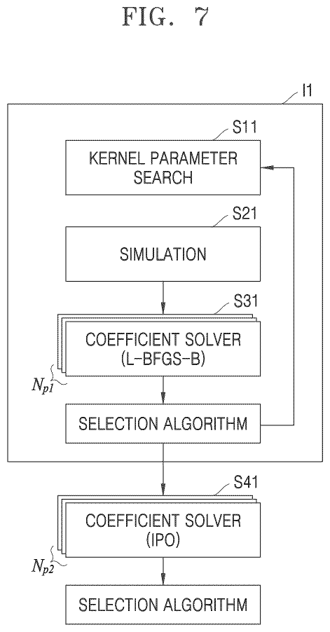

In addition, in the method of optimizing the OPC model, according to the various example embodiments, the accuracy of optimization may be improved by first achieving optimization to a certain degree by using L-BFGS-B and then additionally executing IPO. Detailed thereof will be made later with reference to FIGS. 7, 8, and 10.

That is, in the method of optimizing the OPC model, according to various embodiments, the first linear coefficients may be extracted by executing L-BFGS-B, and then the second linear coefficients may be extracted by executing IPO. Here, the first linear coefficients may indicate result values acquired by executing L-BFGS-B, and the second linear coefficients may indicate result values acquired by executing IPO.

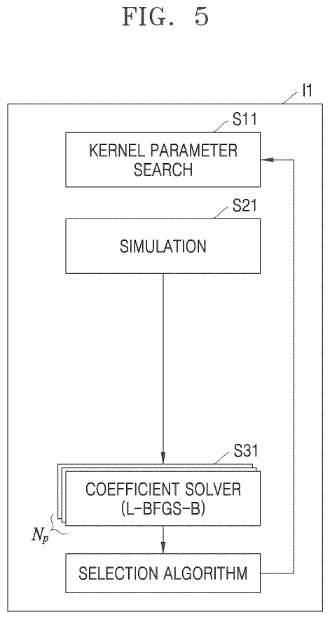

FIG. 5 is a flowchart schematically illustrating first iteration I1 of the method of optimizing the OPC model according to at least one example embodiment.

In the method of optimizing the OPC model, according to at least one example embodiment, the first iteration I1 may be performed. The first iteration I1 may sequentially include updating the kernel parameter in the kernel parameter search, generating the resist image through the simulation (S21), and extracting the first linear coefficients by executing L-BFGS-B as the coefficient solver (S31). That is, the following process may be repeatedly performed: extracting the first linear coefficients by executing L-BFGS-B for each of Nₚ test sets (S31), selecting the most appropriate value from among the first linear coefficients through the selection algorithm, and returning to updating the kernel parameter (S11). In at least one example embodiment, the optimizing of the linear coefficients by only using the first iteration I1 may be applied to a case where there are no inequality constraints and equality constraints, and by doing so, a calculation rate may be improved.

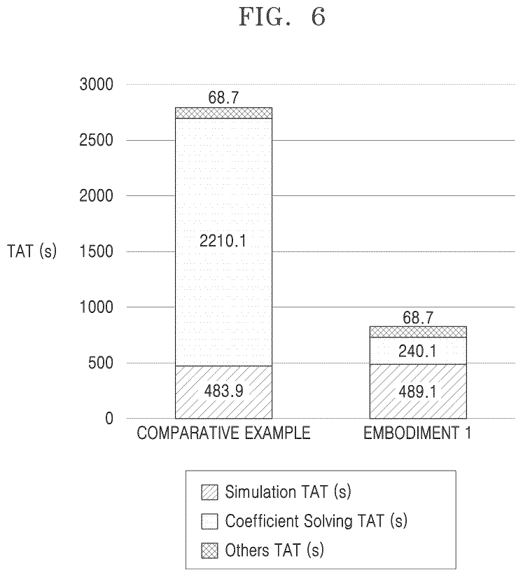

FIG. 6 is a graph illustrating a result of comparing optimization rates of the OPC model in at least one example embodiment and a comparative example. As coefficient solvers, IPO was used in the comparative example, and L-BFGS-B was used in example Embodiment 1. Both the comparative example and Embodiment 1 only have a box constraint, and the number of iterations is fifteen hundred (1500).

When the optimization problem does not have the inequality constraints and the equality constraints, turn around times (TAT) of the comparative example and Embodiment 1 are respectively about 2,763 seconds and about 799 seconds, as illustrated in FIG. 6, and the runtime in Embodiment 1 is improved about 3.5 times the runtime of the comparative example.

More particularly, when only coefficient solving TATs are compared, except the simulation TAT and others TAT, the runtime of Embodiment 1 is improved about 9.2 times the runtime of the comparative example. For reference, error values of the comparative example and Embodiment 1 are at the same level.

FIG. 7 is a flowchart schematically illustrating the method of optimizing the OPC model, according to at least one example embodiment. In the method of optimizing the OPC model, according to at least one example embodiment, the second linear coefficients may be extracted (S41) by additionally executing the IPO, as the coefficient solver, after the first iteration I1 is complete.

Referring to FIG. 7, as described above with reference to FIG. 5, the first iteration I1 may sequentially include updating the kernel parameter in the kernel parameter search (S11), calculating the resist image through the simulation (S21), and extracting the first linear coefficients by executing L-BFGS-B as the coefficient solver (S31). Through the first iteration I1 described above, it is possible to get close to the goal of optimizing the linear coefficient. Next, by extracting the second linear coefficients by executing IPO as the coefficient solver (S41), the optimizing may be complete through performing fine-tuning with respect to the linear coefficients optimized through the first iteration I1. That is, a hard constraint (e.g., an equality/inequality constraint) that is not easily achieved in the first iteration I1 where only L-BGFS-B is used may be satisfied in a last operation by using IPO.

In at least one example embodiment, in the extracting of the first linear coefficients (S31), the first linear coefficients may be extracted by executing L-BFGS-B for each of Nₚ₁ test sets, and the selection algorithm may select the most appropriate value from among the first linear coefficients. In the extracting of the second linear coefficients (S41), the second linear coefficients may be extracted by executing IPO for each of Nₚ₂ test sets, and the selection algorithm may select the most appropriate value from among the second linear coefficients. In at least one example embodiment, Nₚ₂ may be a natural number set to be less than less than Nₚ₁, and an optimization runtime of the OPC model may be reduced.

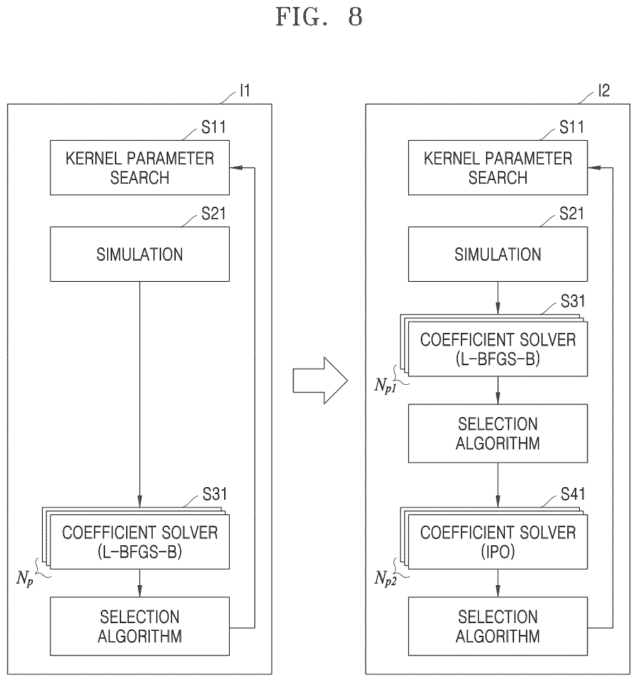

FIG. 8 is a flowchart schematically illustrating the first iteration and the second iteration of the method of optimizing the OPC model according to at least one example embodiment.

In the method of optimizing the OPC model, according to at least one example embodiment, the second iteration I2 may be performed after the first iteration I1 is complete. The second iteration I2 may sequentially include updating the kernel parameter in the kernel parameter search (S11), generating the resist image through the simulation (S21), extracting the first linear coefficients by executing L-BFGS-B as the coefficient solver (S31), and extracting the second linear coefficients by executing IPO as the coefficient solver (S41). In these cases, optimization may be achieved to a certain degree through the first iteration I1 where only L-BFGS-B having a high calculation rate is used, and optimization may be complete through the second iteration I2 where both L-BFGS-B and IPO are used. The second iteration I2 may fulfill a hard constraint (e.g., an equality/inequality constraint) that is not easily achieved in the first iteration where only L-BFGS-B is used.

In at least one example embodiment, the number of first iterations I1 may be greater than the number of second iterations I2. That is, as described above, after achieving most of the optimization by performing a great number of the first iteration I1 having the high calculation rate, the optimization may be complete by performing a small number of the second iteration I2, which has a relatively low calculation rate but by which various constraints may be satisfied.

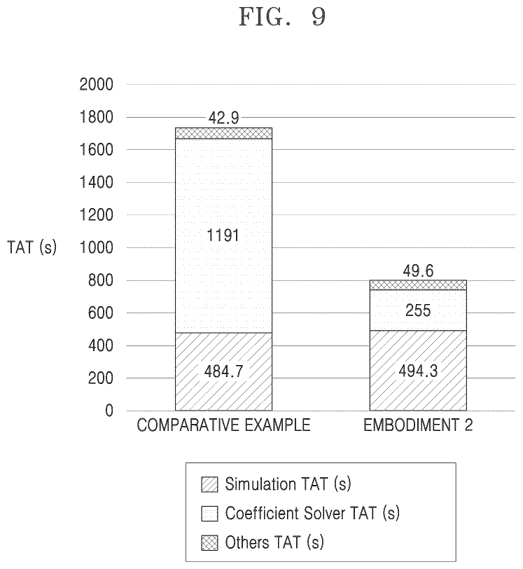

FIG. 9 is a graph illustrating a result of comparing optimization rates of the OPC model in at least one example embodiment and a comparative example. In the comparative example, iteration is performed by using IPO as the coefficient solver, and in example Embodiment 2, as described above with reference to FIG. 8, after performing the first iteration where only L-BFGS-B is used, the second iteration, in which both L-BFGS-B and IPO are used, is performed. The total number of repetitions of each of the comparative example and Embodiment 2 is fifty. In Embodiment 2, the first iteration is performed forty-seven times, and the second iteration is performed three times.

Referring to FIG. 9, TAT (hereinafter, referred to as runtime) of the comparative example and Embodiment 2 are about 1,719 seconds and about 799 seconds, respectively, and the runtime of Embodiment 2 is improved about 2.2 times the runtime of the comparative example.

More particularly, when only coefficient solving runtimes are compared, except the simulation runtimes and other runtimes, the runtime of Embodiment 2 is improved about 4.7 times the runtime of the comparative example. For reference, error values of the comparative example and Embodiment 2 are at the same level, and both the comparative example and Embodiment 2 fulfill a box constraint and an anchor constraint. The anchor constraint is a constraint that is to be necessarily satisfied.

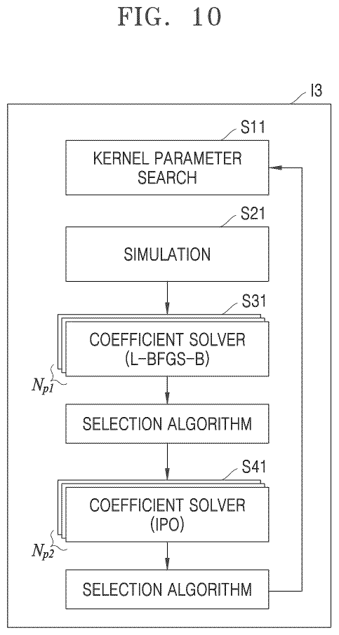

FIG. 10 is a flowchart schematically illustrating third iteration I3 of the method of optimizing the OPC model according to at least one example embodiment.

In the method optimizing the OPC model, according to at least one example embodiment, the third iteration I3 is performed. The third iteration I3 may include updating the kernel parameter in the kernel parameter search (S11), calculating the resist image through the simulation (S21), extracting the first linear coefficients by executing L-BFGS-B as the coefficient solver (S31), and extracting the second linear coefficients by executing IPO as the coefficient solver (S41).

In at least one example embodiment, in the extracting of the first linear coefficient (S31), the first linear coefficients may be extracted by executing L-BFGS-B for each of the Nₚ₁ test sets, and the selection algorithm may select the most appropriate value from among the first linear coefficients. In the extracting of the second linear coefficients (S41), the second linear coefficients may be extracted by executing IPO for each of Nₚ₂ test sets, and the selection algorithm may select the most appropriate value from among the second linear coefficients. In at least one example embodiment, Nₚ₂ is set less than Nₚ₁ and reduces the optimization runtime of the OPC model, and by including IPO, may satisfy a hard constraint (e.g., an equality/inequality constraint) that is not practically achievable using only L-BFGS-B.

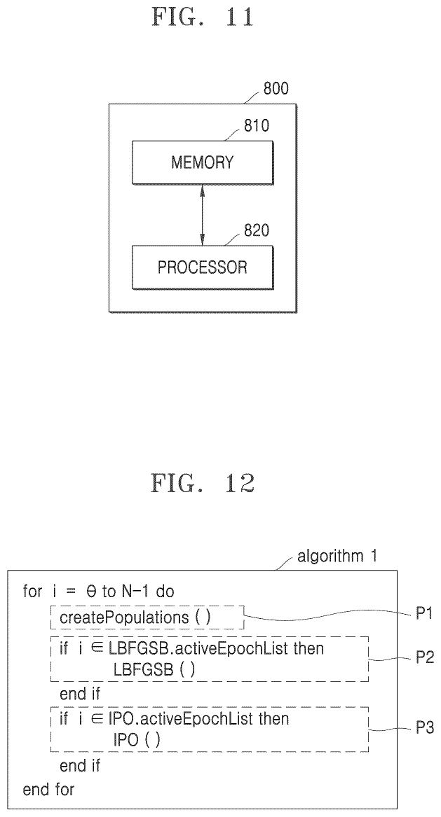

FIG. 11 is a diagram schematically illustrating an electronic device 800 according to at least one example embodiment.

Referring to FIG. 11, the electronic device 800 according to at least one example embodiment may include a memory 810 and one or more processors 820. The memory 810 may be configured to store computer-readable instructions. When the instructions stored in the memory 810 are executed by the processor 820, the processor 820 may process operations defined by the instructions. The memory 810 may include, for example, random access memory (RAM), dynamic random access memory (DRAM), static random access memory (SRAM), or other types of nonvolatile memories known in the technical field. The memory 810 may be configured to store a pre-trained deep learning model.

The one or more processors 820 according to at least one example embodiment may be configured to control general operations of the electronic device 800. The one or more processors 820 may include a device implemented as hardware including a circuit having a physical structure for performing desired operations. The desired operations may include code or instructions in the program. The device implemented as hardware may include a microprocessor, a central processing unit (CPU), a graphics processing unit (GPU), a processor core, a multi-core processor, a multiprocessor, an Application-Specific Integrated Circuit (ASIC), a Field Programming Gate Array (FPGA), a neural processing unit (NPU), and/or the like.

The one or more processors 820 according to at least one example embodiment may be configured to perform the method of optimizing the OPC model described above with reference to FIGS. 1 to 10. For example, the processor 820 may be configured to update the kernel parameter of the OPC model including the linear combination of the kernel function, extract the resist image by performing simulation of the OPC model, based on the updated kernel parameter, and extract the first linear coefficients by executing L-BFGS-B based on the resist image. The one or more processor 820 may be configured to extract the second linear coefficients of the OPC model by executing IPO after the extracting of the first linear coefficients.

Additionally, in at least some example embodiments, the one or more processors may be configured to control a function of a mask manufacturing apparatus. For example, the one or more processors may be configured to generate a mask design based on the output of the OPC model, and provide instructions to the mask manufacturing apparatus to produce a mask based on the generated mask design. In at least some embodiments, the one or more processors 820 may be included in the mask manufacturing apparatus may be further configured to control the mask manufacturing apparatus such that the mask manufacturing apparatus produces a mask based on the output of the one or more processors 820, as described in further detail below.

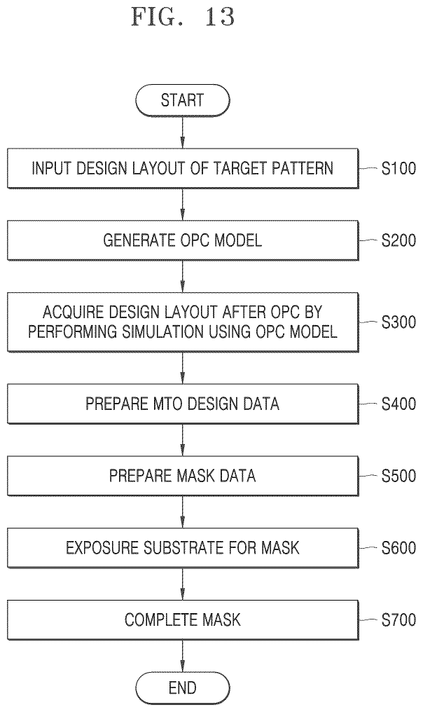

FIG. 12 is a diagram to describe an example of algorithm 1 implementing the method of optimizing the OPC model according to at least one example embodiment. In at least one example embodiment, the electronic device 800 illustrated in FIG. 11 may execute the algorithm ‘algorithm 1’ illustrated in FIG. 12.

To schematically describe the algorithm ‘algorithm 1’ illustrated in FIG. 12, i indicates the number of iterations, and a first portion P1 indicates the number of Nₚ₁ and Nₚ₂ described above, that is, the number of test sets. A second portion P2 indicates that L-BFGS-B is executed when i is included in an LBFGSB.activeEpholist set by a user, and a third portion P3 indicates that IPO is executed when i is included in an IOP.activeEpholist set by the user. Here, the LBFGSB.activeEpholist and the IPO.activeEpochlist are lists preset by the user. For example, the lists may be preset such that L-BFGS-B is executed when i is from zero to ninety-nine and IPO is executed when i is ninety-nine. Here, when i that is from zero to ninety-nine is not on the IPO.activeEpochlist, only L-BFGS-B may be executed, and when i is 99, the algorithm may operate to execute both of L-BFGS-B and IPO.

FIG. 13 is a flowchart schematically illustrating a process of a method of fabricating a mask, the method including an OPC method, according to at least one example embodiment.

In the method of fabricating the mask, including the OPC method according to at least one example embodiment (hereinafter, referred to as ‘the method of fabricating the mask’), the method includes receiving the input of the design layout for the target pattern (S100) to acquiring the design layout after OPC (S300) are sequentially performed. The receiving of the input of the design layout for the target pattern (S100) may be correspond to operation S1000 shown in FIG. 1. Next, the OPC model may be generated (S200). The OPC model may include the first OPC model OM1 and the second OPC model OM2 described above.

Next, the design layout after OPC may be acquired by performing simulation using the OPC model (S300). The acquiring of the design layout by performing the simulation using the OPC model (S300) may include the acquiring of the aerial image by performing the simulation of the first OPC model illustrated in FIG. 1 (S2000) and the optimizing of the second OPC model acquiring the resist image from the aerial image (S3000). As described above, the optimizing of the second OPC model (S3000) may include the updating of the kernel parameter of the OPC model (S10) to the extracting of the second linear coefficients by executing IPO (S40), as illustrated in FIG. 4.

Referring to FIG. 10, MTO design data is prepared and delivered to a mask fabrication team (S400). Generally, MTO may indicate passing data of a final design layout obtained through the OPC method to a mask fabrication team and requesting mask fabrication. Accordingly, in the method of fabricating the mask according to the embodiment, MTO design data may indicate, in conclusion, a design layout after OPC, which is acquired through the OPC method, or data of the design layout. The MTO design data may have a graphic data format used in electronic design automation (EDA) software and the like. For example, the MTO design data may have data formats such as Graphic Data System II (GDS2), Open Artwork System Interchange Standard (OASIS), and the like.

Next, mask data preparation (MDP) may be performed (S500). The MDP may include, for example, i) format conversion, also referred to as fracturing, ii) augmentation of a bar code for mechanical reading, a standard mask pattern for inspection, a job deck, and iii) automatic or manual verification. Here, job-deck may indicate making a text file regarding a series of commands such as arrangement information of multiple mask files, a reference dose, a rate or method of exposure, and the like.

The format conversion, that is, fracturing, may indicate a process of splitting the MTO design data according to regions and converting the MTO design data into a format for an electron beam exposure. The fracturing may include, for example, data operations such as scaling, data-sizing, rotation of data, pattern reflection, color inversion, and the like. In the converting process through the fracturing, it is possible to correct data about numerous systematic errors that may occur somewhere in a process of delivery from the design data to the image on the wafer.

A data correction process with respect to the systematic errors is referred to as mask process correction (MPC), and may include, for example, line-width adjustment, i.e., CD adjustment, an operation of increasing the accuracy of pattern arrangement, and the like. Therefore, the fracturing may be a process that may contribute to improvement in the quality of a final mask and that is performed in advance to correct the mask process. Here, the systematic errors may be caused by distortion occurring in the exposure process, a mask development and etching process, a wafer-imaging process, and the like.

MDP may include MPC. As described above, MPC indicates a process of correcting errors occurring during the exposure process, that is, the systematic errors. Here, the exposure process may collectively include electron beam writing, developing, etching, baking, and the like. In addition, data processing may be performed before the exposure process. Data processing is a pre-processing process with respect to mask data, and may include grammar check with respect to the mask data, prediction on an exposure time, and the like.

After the MDP, a mask substrate is exposed, based on the mask data (S600). Here, exposure may indicate, for example, electron beam writing. Here, electron beam writing may be performed, for example, in a gray writing method by using a multi-beam mask writer (MBMW). In addition, electron beam writing may also be performed by using a variable shape beam (VSB) writer.

After the preparing of the mask data, before the exposure process, a process of converting the mask data to pixel data may be performed. The pixel data, which is data directly used in actual exposure, may include data about shapes to be exposed and data for a dose assigned to each of the shapes. Here, the data about shapes may include bit-map data converted from the shape data, i.e., vector data, through rasterization and the like.

After the exposure process, the mask is completely fabricated by performing a series of processes (S700). The series of processes may include, for example, processes such as developing, etching, washing, and the like. In addition, the series of processes for fabricating the mask may include a measuring process, a defect inspecting process, and a defect repairing process. Furthermore, the series of processes for fabricating the mask may include a pellicle coating process. Here, the pellicle coating process may indicate a process of attaching a pellicle onto a surface of the mask to protect the mask from subsequent contamination during delivery of the mask and an available time of the mask when there is no contaminated particle or chemical stain through final washing and inspection.

Although the inventive concepts have been described with reference to embodiments illustrated in the drawings, the descriptions have been made only to provide examples, and it would be understood to those skilled in the art that various modifications and other equivalent embodiments may be made based thereon. Accordingly, the scope of the inventive concepts will be determined based on the following claims.

While the inventive concepts have been particularly shown and described with reference to embodiments thereof, it will be understood that various changes in form and details may be made therein without departing from the spirit and scope of the following claims.

What is claimed is:

1. A method of improving an optical proximity correction (OPC) model including a linear combination of a kernel function, the method comprising:
updating a kernel parameter of the OPC model;
generating a resist image by performing simulation of the OPC model based on the updated kernel parameter; and
extracting first linear coefficients of the OPC model by executing a Limited memory Broyden Fletcher Goldfarb Shanno with Bounds (L-BFGS-B) based on the resist image.

2. The method of claim 1, further comprising:
extracting second linear coefficients of the OPC model by executing Inter Point Optimizer (IPO) after the extracting of the first linear coefficients.

3. The method of claim 2, wherein the updating the kernel parameter, the generating the resist image, and the extracting the first linear coefficients are sequentially included in a first iteration, and wherein the method comprises performing at least one of the first iteration.

4. The method of claim 3, wherein the extracting the second linear coefficients is performed after the at least one first iteration is complete.

5. The method of claim 3, further comprising:
performing at least one second iteration after the at least one first iteration is complete,
the second iteration sequentially comprising updating the kernel parameter, the generating the resist image, the extracting the first linear coefficients, and the extracting the second linear coefficients.

6. The method of claim 5, wherein a number of the at least one first iteration is greater than a number of the at least one second iteration.

7. The method of claim 2, further comprising:
performing at least one of a third iteration,
wherein the third iteration sequentially comprises the updating the kernel parameter, the generating the resist image, the extracting the first linear coefficients, and the extracting the second linear coefficients.

8. The method of claim 7, wherein
the extracting of the first linear coefficients comprises executing the L-BFGS-B for each of Nₚ₁ test sets, the Nₚ₁ being a natural number, and
the extracting of the second linear coefficients comprises executing the IPO for each of Nₚ₂ test sets, the Nₚ₂ being a natural number less than the Nₚ₁.

9. The method of claim 1, further comprising:
determining a loss by comparing a critical dimension (CD) of the resist image with a CD of a pattern on a wafer.

10. The method of claim 9, further comprising:
adjusting the kernel parameter and linear coefficients of the OPC model such that the loss is reduced.

11. An electronic device comprising:
a memory storing at least one instruction; and
a processor configured to, by executing the at least one instruction stored in the memory, cause the electronic device to
update a kernel parameter of an optical proximity correction (OPC) model, the OPC model comprising a linear combination of a kernel function,
generate a resist image by performing simulation of the OPC model based on the updated kernel parameter, and
extract first linear coefficients of the OPC model by an executing Limited memory Broyden Fletcher Goldfarb Shanno with Bounds (L-BFGS-B) based on the resist image.

12. The electronic device of claim 11, wherein
the processor is further configured to cause the electronic device to extract second linear coefficients of the OPC model by executing Inter Point Optimizer (IPO) after the extracting of the first linear coefficients.

13. The electronic device of claim 12, wherein the processor is further configured to cause the electronic device to
extract the first linear coefficients by executing L-BFGS-B for each of Nₚ₁ test sets, the Nₚ₁ being a natural number, and
extract the second linear coefficients by executing IPO for each of Nₚ₂ test sets, the Nₚ₂ being a natural number less than the Nₚ₁.

14. The electronic device of claim 12, wherein
the updating the kernel parameter, generating the resist image, and the extracting the first linear coefficients are sequentially included in a first iteration, and wherein the processor is configured to cause the electronic device to perform at least one of the first iteration.

15. The electronic device of claim 14, wherein
the processor is further configured to perform at least one second iteration after the at least one first iteration is complete, and
the second iteration sequentially comprises the updating the kernel parameter, the generating the resist image, the extracting the first linear coefficients, and the extracting the second linear coefficients.

16. The electronic device of claim 15, wherein a number of the at least one first iterations are greater than a number of the at least one second iterations.

17. The electronic device of claim 12, wherein
the processor is further configured to perform at least one of a third iteration, and
the third iteration sequentially comprises the updating the kernel parameter, the generating the resist image, the extracting the first linear coefficients, and the extracting the second linear coefficients.

18. An optical proximity correction (OPC) method comprising:
receiving an input of a design layout of a target pattern;
acquiring an aerial image from the design layout by performing simulation of a first OPC model to which optical phenomena in an exposure process are reflected; and
improving a second OPC model, which acquires a resist image from the aerial image, by reflecting characteristics of a photoresist (PR) in the exposure process,
wherein the improving the second OPC model comprises
updating a kernel parameter of the second OPC model, the second OPC model comprising a linear combination of a kernel function,
generating a resist image by performing simulation on the second OPC model based on the updated kernel parameter,
extracting first linear coefficients of the OPC model by executing a Limited memory Broyden Fletcher Goldfarb Shanno with Bounds (L-BFGS-B) based on the resist image, and
extracting second linear coefficients of the OPC model by executing Inter Point Optimizer (IPO) after the extracting of the first linear coefficients.

19. The OPC method of claim 18, wherein the updating the kernel parameter, the generating the resist image, and the extracting the first linear coefficients are sequentially included in a first iteration, and wherein the method comprises performing at least one of the first iteration.

20. The OPC method of claim 19, wherein
the improving the second OPC model comprises performing at least one second iteration after the at least one first iteration is complete, and
the second iteration comprises the extracting the second linear coefficients.
